(19) United States
(12) Patent Application Publication
(10) Pub. No.: US 2006/0131686 A1
(43) Pub. Date: Jun. 22, 2006

(54) LOCOS-based junction-pinched schottky rectifier and its manufacturing methods

(75) Inventor: Ching-Yuan Wu, Hsinchu (TW)

Correspondence Address: DENNISON, SCHULTZ, DOUGHERTY & MACDONALD, 1727 KING STREET, SUITE 105, ALEXANDRIA, VA, 22314, US

(73) Assignee: SILICON-BASE TECHNOLOGY CORP.

(21) Appl. No.: 11/014,838

(22) Filed: Dec. 20, 2004

(51) Int. Cl. H01L 27/095; H01L 29/47; H01L 29/812; H01L 31/07; H01L 31/108

(52) U.S. Cl. 257/484

(57) ABSTRACT

The LOCOS-based junction-pinched Schottky rectifier comprises a raised diffusion guard ring surrounded by an outer LOCOS field oxide layer, a raised diffusion grid or a plurality of raised diffusion rings or stripes surrounded by the raised diffusion guard ring, a plurality of recessed semiconductor surfaces formed on a lightly-doped epitaxial semiconductor layer surrounded by the raised diffusion guard ring and the raised diffusion grid or by the raised diffusion guard ring and the plurality of raised diffusion rings or stripes, and a metal silicide layer or a metal layer being at least formed over a portion of the raised diffusion guard ring, the plurality of recessed semiconductor surfaces and the raised diffusion grid or the plurality of raised diffusion rings or stripes. A plurality of compensated diffusion layers can be formed in surface portions of the lightly-doped epitaxial semiconductor layer under the plurality of recessed semiconductor surfaces.

### BACKGROUND OF THE INVENTION

1. Field of the Invention

The present invention relates generally to a Schottky barrier diode (SBD) and its manufacturing method and, more particularly, to a LOCOS-based junction-pinched Schottky (LBJPS) rectifier and its manufacturing methods.

2. Description of the Related Art

A Schottky barrier diode with a metal-semiconductor contact is known to be a majority carrier diode for high-speed switching and high-frequency rectification. In general, a diffusion guard ring is required for forming the Schottky barrier diode in order to eliminate edge leakage current and soft breakdown due to the metal-semiconductor contact. However, a deeper junction depth of the diffusion guard ring is required to reduce junction curvature effect on reverse breakdown voltage of the Schottky barrier diode. As a consequence, it is difficult to simultaneously obtain a lower forward voltage drop and a higher reverse breakdown voltage for a conventional Schottky barrier diode. More importantly, a higher reverse leakage current due to image-force lowering effect on Schottky barrier height becomes a major concern for low power loss applications.

FIG. 1A shows a schematic cross-sectional view for a junction barrier controlled Schottky (JBS) rectifier of the prior art, in which a p diffusion grid 114 is formed in some surface portions of a lightly-doped n⁺ epitaxial silicon layer 112 on a heavily-doped n⁺ silicon substrate 110 surrounded by a field oxide layer 116 and a contact metal layer 113 is formed on the p diffusion grid 114 and the lightly-doped n⁻ epitaxial silicon layer 112 surrounded by the p diffusion grid 114. The p diffusion grid 114 forms a p-n junction depletion region with respect to the lightly-doped n⁻ epitaxial silicon layer 112 to pinch surface portions of the lightly-doped n⁻ epitaxial silicon layer 112 under the contact metal layer 113 if a small reverse bias is applied, so reverse leakage current due to the image-force lowering effect of Schottky barrier contacts can be eliminated and, therefore, the contact metal layer 113 with a low barrier height can be used to reduce forward voltage drop. Apparently, surface area occupied by the p diffusion grid 114 becomes larger as a junction depth of the p diffusion grid 114 is deeper to reduce junction curvature effect for obtaining higher reverse breakdown voltage. Moreover, parasitic series resistance due to the lightly-doped n⁻ epitaxial silicon layer 112 surrounded by and formed below the p diffusion grid 114 becomes a limiting factor for reducing the forward voltage drop in high current or high voltage applications. A typical example of the prior art can refer to U.S. Pat. No. 4,641,174.

FIG. 1B shows a schematic cross-sectional view for a trench MOS barrier Schottky (TMBS) rectifier of the prior art, in which a trench grid is formed in surface portions of the lightly-doped n⁻ epitaxial silicon layer 112, a liner oxide layer 120 is formed over a trench surface, and a planarized metal layer 122 is formed over the liner oxide layer 120 and the lightly-doped n⁻ epitaxial silicon layer 112 surrounded by the trench grid. Apparently, surface area occupied by the trench grid is smaller than that of the p diffusion grid 114 shown in FIG. 1A and the leakage current between the trench grid and the lightly-doped n⁻ epitaxial silicon layer 112 can be eliminated. However, a MOS capacitor formed in the trench grid will exhibit a limited depletion layer extension under a reverse blocking state, so surface area of a Schottky metal contact is small and forward voltage drop is mainly limited by parasitic series resistance of the lightly-doped n⁻ epitaxial silicon layer 112 surrounded by and formed below the trench grid. As a consequence, the trench MOS barrier Schottky (TMBS) rectifier is limited to low forward current applications. A typical example of the prior art can refer to U.S. Pat. No. 5,612,567.

It is therefore a major objective of the present invention to offer a LOCOS-based junction-pinched Schottky (LBJPS) rectifier with a raised diffusion grid or a plurality of raised diffusion rings or stripes and a plurality of recessed semiconductor surfaces or a plurality of recessed semiconductor rings or stripes for forming a metal-semiconductor contact to simultaneously obtain a lower forward voltage drop and a higher reverse breakdown voltage.

It is another objective of the present invention to offer a LOCOS-based junction-pinched Schottky (LBJPS) rectifier with a plurality of recessed semiconductor surfaces or a plurality of recessed semiconductor rings or stripes with compensated diffusion layers being formed in surface portions of a lightly-doped epitaxial silicon layer to simultaneously eliminate junction curvature effect on reverse breakdown voltage and image-force lowering effect on reverse leakage current.

It is an important objective of the present invention to offer a LOCOS-based junction-pinched Schottky (LBJPS) rectifier being fabricated without expensive processes and critical process steps.

### SUMMARY OF THE INVENTION

The present invention discloses a LOCOS-based junction-pinched Schottky (LBJPS) rectifier and its manufacturing methods. The LOCOS-based junction-pinched Schottky (LBJPS) rectifier comprises a raised diffusion guard ring being surrounded by an outer LOCOS field oxide layer, a raised diffusion grid or a plurality of raised diffusion rings or stripes being surrounded by the raised diffusion guard ring, a plurality of recessed semiconductor surfaces being formed on a lightly-doped epitaxial silicon layer surrounded by the raised diffusion grid and the raised diffusion guard ring or by a plurality of raised diffusion rings or stripes and the raised diffusion guard ring, and a metal silicide layer or a metal layer being at least formed on a metal contact region comprising a portion of the raised diffusion guard ring, the plurality of recessed semiconductor surfaces, and the raised diffusion grid or the plurality of raised diffusion rings or stripes. The plurality of recessed semiconductor surfaces are formed by removing a plurality of inner LOCOS field oxide layers. A plurality of compensated diffusion layers can be formed in surface portions of the lightly-doped epitaxial silicon layer under the plurality of recessed semiconductor surfaces. The outer LOCOS field oxide layer and the plurality of inner LOCOS field oxide layers are formed by a local oxidation of silicon (LOCOS) process in a steam or wet oxygen ambient. The plurality of compensated diffusion layers are formed by implanting compensated doping impurities across a pad oxide layer into surface portions of the lightly-doped epitaxial silicon layer in the outer field oxide region (OFOXR) and the plurality of inner field oxide regions (IFOXR) before performing a LOCOS process. The metal contact region is patterned by a masking photoresist step with or without a hard masking layer being formed over an outer portion of a thermal oxide layer formed on the raised diffusion guard ring and a portion of the outer LOCOS field oxide layer.

### BRIEF DESCRIPTION OF THE DRAWINGS

FIG. 1A and FIG. 1B show schematic cross-sectional views of two different Schottky barrier rectifiers of the prior art, in which FIG. 1A shows a schematic cross-sectional view of a junction barrier controlled Schottky (JBS) rectifier and FIG. 1B shows a schematic cross-sectional view of a trench MOS barrier Schottky (TMBS) rectifier.

FIG. 2A through FIG. 2F show process steps and their schematic cross-sectional views of fabricating a first-type LOCOS-based junction-pinched Schottky (LBJPS) rectifier of the present invention.

FIG. 3A through FIG. 3E show process steps after FIG. 2B and their schematic cross-sectional views of fabricating a second-type LOCOS-based junction-pinched Schottky (LBJPS) rectifier of the present invention.

FIG. 4A and FIG. 4B show simplified process steps after FIG. 2D and their schematic cross-sectional views of fabricating a third-type LOCOS-based junction-pinched Schottky (LBJPS) rectifier of the present invention.

FIG. 5A and FIG. 5B show simplified process steps after FIG. 3C and their schematic cross-sectional views of fabricating a fourth-type LOCOS-based junction-pinched Schottky (LBJPS) rectifier of the present invention.

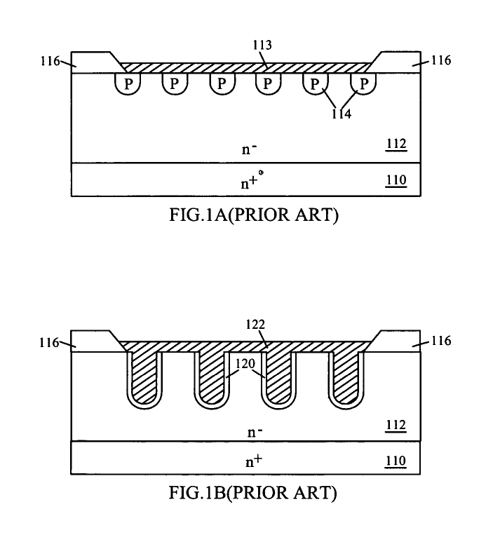

### DETAILED DESCRIPTION OF THE PREFERRED EMBODIMENTS

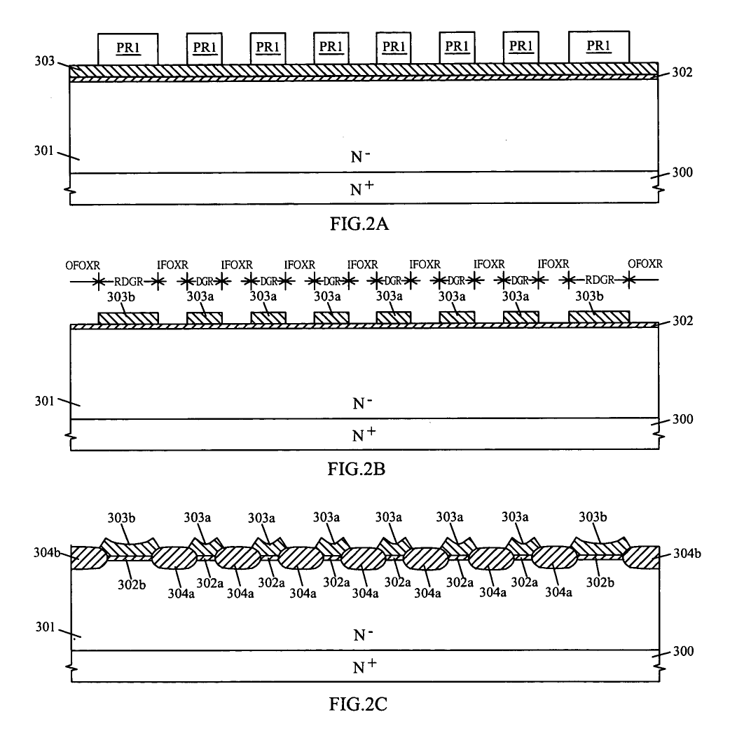

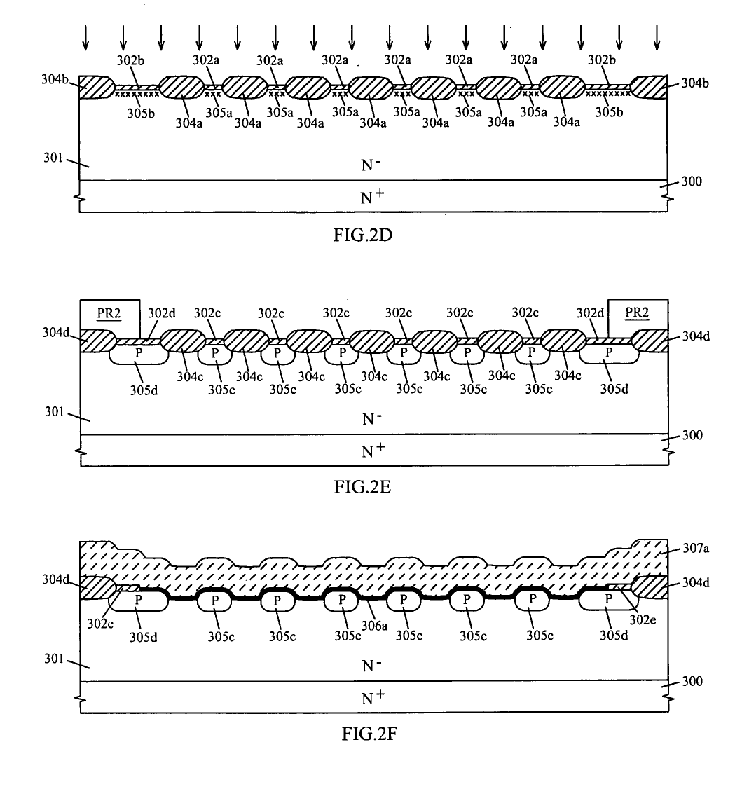

Referring now to FIG. 2A through FIG. 2F, there are shown process steps and their schematic cross-sectional views of fabricating a first-type LOCOS-based junction-pinched Schottky (LBJPS) rectifier of the present invention.

FIG. 2A shows that a pad oxide layer 302 is formed on an epitaxial semiconductor substrate 301/300 of a first conductivity type; a masking dielectric layer 303 is then formed on the pad oxide layer 302; and subsequently, a first masking photoresist (PRI) step is formed to define a raised diffusion grid region (DGR) and a raised diffusion guard ring region (RDGR). The pad oxide layer 302 is preferably a thermal silicon dioxide layer and has a thickness between 200 Angstroms and 500 Angstroms. The masking dielectric layer 303 is preferably made of silicon nitride as deposited by low-pressure chemical vapor deposition (LPCVD) and its thickness is preferably between 800 Angstroms and 1500 Angstroms. The epitaxial semiconductor substrate 301/300 comprises a lightly-doped epitaxial silicon layer 301 formed on a heavily-doped silicon substrate 300. The doping concentration in the lightly-doped epitaxial silicon layer 301 is preferably between 10¹⁴/cm³ and 10¹⁷/cm³ and the epitaxial layer thickness is preferably between 2 μm and 35 μm. The doping concentration in the heavily-doped silicon substrate 300 is preferably between 5×10⁸/cm³ and 10²⁰/cm³ and the thickness is between 400 μm and 800 μm, depending on wafer size. From FIG. 2A, it is clearly seen that the first conductivity type means an n-type. It should be noted that the raised diffusion grid region (DGR) is surrounded by the raised diffusion guard ring region (RDGR) and can be replaced by a plurality of raised diffusion ring regions or a plurality of raised diffusion stripe regions.

FIG. 2B shows that the masking dielectric layers 303 outside of the patterned first masking photoresist (PRI) are removed by using anisotropic dry etching and the patterned first masking photoresist (PR1) are then removed. The patterned masking dielectric layer 303b represents a region for forming a raised diffusion guard ring and the patterned masking dielectric layer 303a represents regions for forming a raised diffusion grid, a plurality of raised diffusion rings or a plurality of raised diffusion stripes.

FIG. 2C shows that a local oxidation of silicon (LOCOS) process is performed in a steam or wet oxygen ambient at a temperature between 950 and 1150 to grow an outer LOCOS field oxide layer 304b in the outer field oxide region (OFOXR) and an inner LOCOS field oxide layer 304a in the raised diffusion grid, each of the plurality of raised diffusion rings or each of the plurality of raised diffusion stripes. The thickness of the inner/outer LOCOS field oxide layers 304a/304b is preferably between 6000 Angstroms and 10000 Angstroms.

FIG. 2D shows that the patterned masking dielectric layers 303a/303b are removed by hot-phosphoric acid and ion implantation is then performed in a self-aligned manner to implant doping impurities of a second conductivity type across the patterned pad oxide layers 302b/302a in the raised diffusion guard ring region (RDGR) and the raised diffusion grid region (DGR) or the plurality of raised diffusion ring or stripe regions (not shown) into surface portions of the lightly-doped epitaxial silicon layer 301 to form implanted regions 305b/305a.

FIG. 2E shows that a drive-in process is performed to form a raised diffusion guard ring 305d and a raised diffusion grid 305c; the patterned pad oxide layers 302b/302a and the outer/inner LOCOS field oxide layers 304b/304a are simultaneously grown thicker; and subsequently, a second masking photoresist (PR2) step is performed to define a metal contact region surrounded by the patterned second masking photoresist (PR2).

FIG. 2F shows that the thermal oxide layer 302d/302c and the inner LOCOS field oxide layers 304c outside of the patterned second masking photoresist (PR2) are removed by using buffered hydrofluoric acid; the patterned second masking photoresist (PR2) are stripped and a wafer cleaning process is performed; a well-known self-aligned silicidation process is performed to form a metal silicide layer 306a over an exposed silicon surface comprising a portion of the raised diffusion guard ring 305d, the raised diffusion grid 305c and a plurality of recessed semiconductor surfaces surrounded by the raised diffusion grid 305c and the raised diffusion guard ring 305d; and subsequently, a patterned metal layer 307a is formed over the metal silicide layer 306a, an outer portion of the thermal oxide layer 302e and a portion of the outer LOCOS field oxide layer 304d. The metal silicide layer 306a is preferably a refractory metal silicide layer and the patterned metal layer 307a comprises a silver (Ag), aluminum (Al) or gold (Au) layer on a barrier metal layer. It should be noted that a metal layer can be used as a Schottky barrier metal layer, such as aluminum, instead of a multilayered structure with the metal silicide layer 306a.

From FIG. 2F, it is clearly seen that the first-type LOCOS-based junction-pinched Schottky (LBJPS) rectifier exhibits the following advantages and features as compared to the prior art:
(a) The first-type LOCOS-based junction-pinched Schottky rectifier of the present invention offers a narrow width for forming a raised diffusion grid or a plurality of raised diffusion rings or stripes to improve area efficiency for Schottky barrier contact by using bird's beak extension of a well-known LOCOS technique.
(b) The first-type LOCOS-based junction-pinched Schottky rectifier of the present invention offers a raised diffusion guard ring and a raised diffusion grid or a plurality of raised diffusion rings or stripes with a smaller junction depth to obtain a higher breakdown voltage.
(c) The first-type LOCOS-based junction-pinched Schottky rectifier of the present invention offers a plurality of recessed semiconductor surfaces for forming Schottky barrier contacts to reduce forward voltage drop due to parasitic series resistance of a lightly-doped epitaxial semiconductor layer.
(d) The first-type LOCOS-based junction-pinched Schottky rectifier of the present invention offers a relatively smooth surface to improve metal step coverage for high forward current operation.

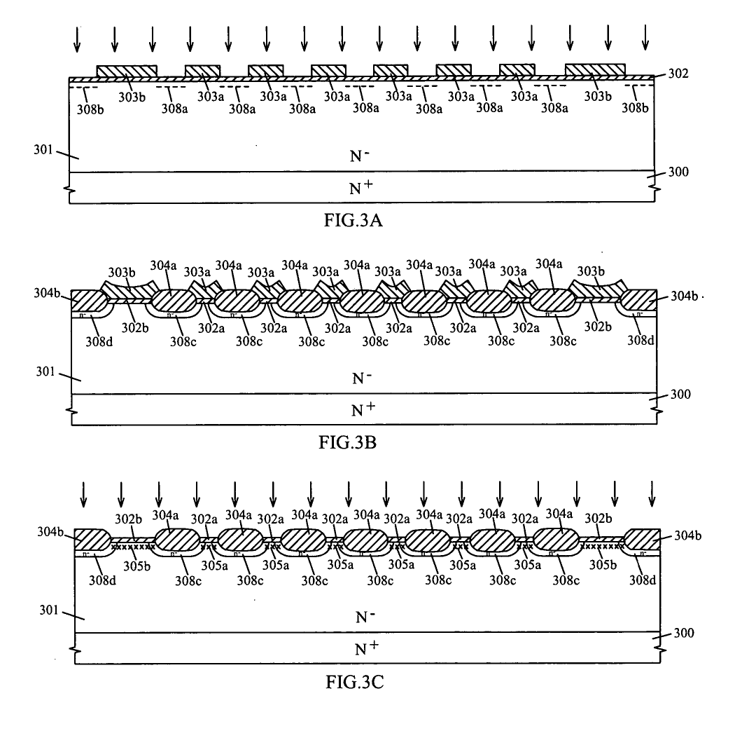

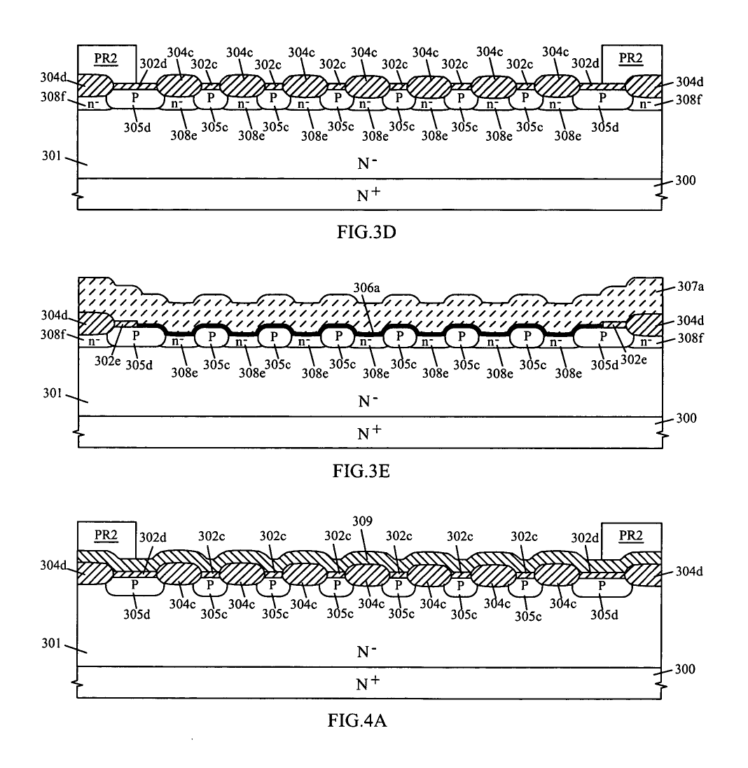

Referring now to FIG. 3A through FIG. 3E, there are shown process steps after FIG. 2B and their schematic cross-sectional views of fabricating a second-type LOCOS-based junction-pinched Schottky (LBJPS) rectifier of the present invention.

FIG. 3A shows that ion implantation is performed in a self-aligned manner by implanting doping impurities of a second conductivity type across the pad oxide layer 302 into surface portions of the lightly-doped epitaxial silicon layer 301 to form compensated implant regions 308b/308a in the outer/inner field oxide regions (OFOXR/IFOXR).

FIG. 3B shows that a local oxidation of silicon (LOCOS) process is performed in a steam or wet oxygen ambient at a temperature between 950 and 1100 to form an outer LOCOS field oxide layer 304b in the outer field oxide region (OFOXR) and an inner LOCOS field oxide layer 304a in the inner field oxide region (IFOXR) and simultaneously the compensated implant regions 308b/308a are driven in to form compensated diffusion layers 308d/308c of the first conductivity type. The compensated diffusion layers 308d/308c will have a lower doping profile of the first conductivity type as compared to that in the lightly-doped epitaxial silicon layer 301.

FIG. 3C shows that the patterned masking dielectric layers 303b/303a are removed by hot-phosphoric acid; and subsequently, ion implantation is performed in a self-aligned manner by implanting doping impurities of the second conductivity type across the patterned pad oxide layers 302b/302a into surface portions of the lightly-doped epitaxial silicon layer 301 in the raised diffusion guard ring region (RDGR) and the raised diffusion grid region (DGR) to form implanted regions 305b/305a of the second conductivity type. The implanted dose is preferably between 10¹³/cm² and 10¹⁴/cm².

FIG. 3D shows that a drive-in process is performed to form a raised diffusion guard ring 305d and a raised diffusion grid 305c and simultaneously the compensated diffusion layers 308d/308c are also driven in deeper; and similarly, the outer/inner LOCOS field oxide layers 304b/304a and the patterned pad oxide layers 302b/302a are grown thicker.

FIG. 3D also shows that a second masking photoresist (PR2) step is performed to define a metal contact region surrounded by the patterned second masking photoresist (PR2), as described in FIG. 2E.

FIG. 3E shows that the thermal oxide layers 302d/302c and the inner LOCOS field oxide layer 304c in the metal contact region are removed by buffered hydrofluoric acid and the patterned second masking photoresist (PR2) are stripped; a metal silicide layer 306a is then formed by a well-known self-aligned silicidation process; and subsequently, a patterned metal layer 307a is formed over the metal silicide layer 306a, a portion of the patterned thermal oxide layer 302e and a portion of the outer LOCOS field oxide layer 304d, as described in FIG. 2F. It should be emphasized that the raised diffusion grid 305c can be replaced by a plurality of raised diffusion rings or a plurality of raised diffusion stripes surrounded by the raised diffusion guard ring 305d, as described in the first-type LOCOS-based junction-pinched Schottky (LBJPS) rectifier. Apparently, compared to the first-type LOCOS-based junction-pinched Schottky rectifier, the advantages and features of the second-type LOCOS-based junction-pinched Schottky (LBJPS) rectifier can be summarized below:
(a) The second-type LOCOS-based junction-pinched Schottky rectifier of the present invention offers a compensated diffusion layer under each of the plurality of recessed semiconductor surfaces to reduce doping concentration of the lightly-doped epitaxial silicon layer surrounded by the raised diffusion grid and the raised diffusion guard ring, so area of the Schottky barrier contact can be increased to further increase forward operation current.
(b) The second-type LOCOS-based junction-pinched Schottky rectifier of the present invention offers a compensated diffusion layer under each of the plurality of recessed semiconductor surfaces to eliminate image-force lowering effect on Schottky barrier height, so reverse leakage current can be reduced.
(c) The second-type LOCOS-based junction-pinched Schottky rectifier of the present invention offers a compensated diffusion layer to eliminate junction curvature effect of the raised diffusion guard ring and the raised diffusion grid, so a higher reverse breakdown voltage can be easily obtained.

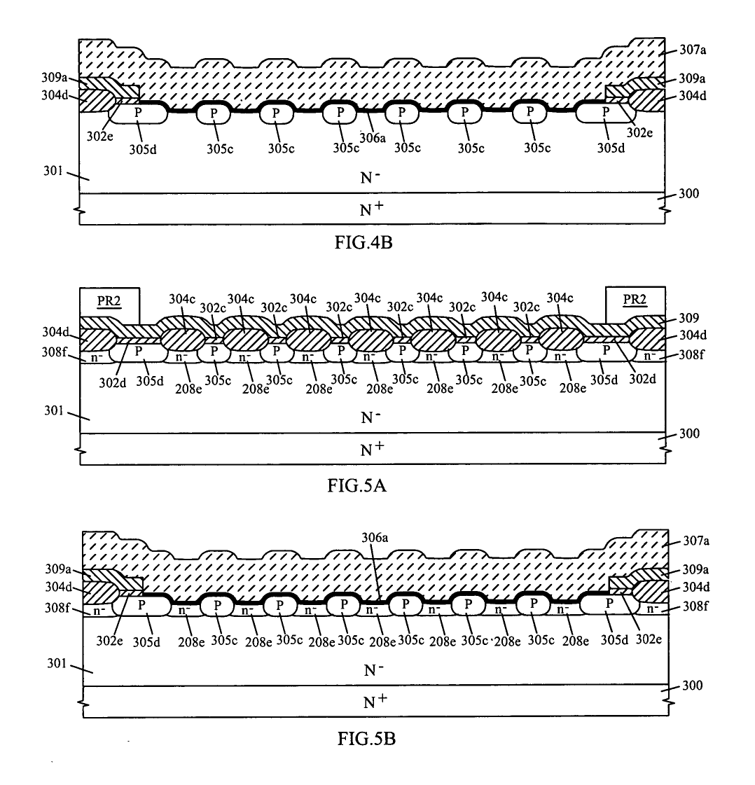

Referring now to FIG. 4A and FIG. 4B, there are shown simplified process steps after FIG. 2D and their schematic cross-sectional views of fabricating a third-type LOCOS-based junction-pinched Schottky rectifier of the present invention.

FIG. 4A shows that after a drive-in process, a hard masking layer 309 is formed over a formed structure surface; and subsequently, a second masking photoresist (PR2) step is performed to define the metal contact region as described in FIG. 2E. The hard masking layer 309 is preferably made of silicon nitride as deposited by LPCVD or plasma CVD and its thickness is preferably between 1000 Angstroms and 3000 Angstroms.

FIG. 4B shows that the hard masking layer 309 outside of the patterned second masking photoresist (PR2) is removed by anisotropic dry etching and subsequently the thermal oxide layers 302d/302c and the inner LOCOS field oxide layers 304c outside of the patterned second masking photoresist (PR2) are removed by buffered hydrofluoric acid; the patterned second masking photoresist (PR2) are stripped and a wafer cleaning process is then performed; a well-known self-aligned silicidation process is performed to form a metal silicide layer 306a over the metal contact region; and a patterned metal layer 307a is formed, as described in FIG. 2F. From FIG. 4B, it is clearly seen that the patterned hard masking layer 309a not only acts as an etching stop layer for patterning a thick metal layer 307 (not shown) but also acts as a passivation or protection layer, as compared to FIG. 2F.

Referring now to FIG. 5A and FIG. 5B, there are shown simplified process steps after FIG. 3C and their schematic cross-sectional views of fabricating a fourth-type LOCOS-based junction-pinched Schottky rectifier of the present invention.

Following the same process steps as described in FIG. 4A, FIG. 5A can be easily obtained. Similarly, following the same process steps as described in FIG. 4B, FIG. 5B can be easily obtained. Compared to FIG. 3E, FIG. 5B offers a patterned hard masking layer 309a to act as an etching stop layer for patterning a thick metal layer (not shown) and a passivation or protection layer.

It should be emphasized again that the raised diffusion grid 305c shown in FIG. 4B and FIG. 5B can be replaced by a plurality of raised diffusion rings or a plurality of raised diffusion stripes. Moreover, the metal silicide layer 306a can be deleted and a patterned metal layer such as an aluminum layer can be directly formed on the metal contact region.

While the present invention has been particularly shown and described with a reference to the present examples and embodiments as considered as illustrative and not restrictive. Moreover, the present invention is not to be limited to the details given herein, it will be understood by those skilled in the art that various changes in forms and details may be made without departure from the true spirit and scope of the present invention

What is claimed is:

1. A LOCOS-based junction-pinched Schottky rectifier, comprising:
a semiconductor substrate of a first conductivity type, wherein the semiconductor substrate comprises a lightly-doped epitaxial semiconductor layer being formed on a heavily-doped semiconductor substrate;
a raised diffusion guard ring of a second conductivity type being surrounded by an outer LOCOS field oxide layer and formed in a surface portion of the lightly-doped epitaxial semiconductor layer, wherein a raised diffusion structure of the second conductivity type being surrounded by the raised diffusion guard ring is simultaneously formed in surface portions of the lightly-doped epitaxial semiconductor layer;
a plurality of recessed semiconductor surfaces being formed on the lightly-doped epitaxial semiconductor layer surrounded by the raised diffusion guard ring and the raised diffusion structure, wherein the plurality of recessed semiconductor surfaces are formed by removing a plurality of inner LOCOS field oxide layers; and
a contact metal layer being at least formed over a metal contact region, wherein the metal contact region comprises a portion of the raised diffusion guard ring, the plurality of recessed semiconductor surfaces and the raised diffusion structure.

2. The LOCOS-based junction-pinched Schottky rectifier according to claim 1, wherein the outer LOCOS field oxide layer and the plurality of inner LOCOS field oxide layers are formed by a local oxidation of silicon (LOCOS) process in a steam or wet oxygen ambient.

3. The LOCOS-based junction-pinched Schottky rectifier according to claim 1, wherein the raised diffusion guard ring and the raised diffusion structure are formed in a self-aligned manner by implanting doping impurities of the second conductivity type across patterned pad oxide layers into surface portions of the lightly-doped epitaxial semiconductor layer surrounded by the outer LOCOS field oxide layer and the plurality of inner LOCOS field oxide layers.

4. The LOCOS-based junction-pinched Schottky rectifier according to claim 1, wherein a plurality of compensated diffusion layers of the first conductivity type are formed in surface portions of the lightly-doped epitaxial semiconductor layer under the plurality of recessd semiconductor surfaces by implanting doping impurities of the second conductivity type across a pad oxide layer through implantation windows surrounded by patterned masking dielectric layers before performing a LOCOS process.

5. The LOCOS-based junction-pinched Schottky rectifier according to claim 1, wherein the raised diffusion structure comprises a raised diffusion grid, a plurality of raised diffusion rings or a plurality of raised diffusion stripes.

6. The LOCOS-based junction-pinched Schottky rectifier according to claim 1, wherein the contact metal layer comprises a refractory metal silicide layer being formed by a self-aligned silicidation process.

7. The LOCOS-based junction-pinched Schottky rectifier according to claim 1, wherein the raised diffusion guard ring and the raised diffusion structure are formed by a conventional diffusion process using a liquid source, a solid source or a gas source with patterned pad oxide layers on the lightly-doped epitaxial semiconductor layer being removed.

8. The LOCOS-based junction-pinched Schottky rectifier according to claim 1, wherein the metal contact region is patterned through a hard masking layer being formed over the outer LOCOS field oxide layer, the plurality of inner LOCOS field oxide layers, and thermal oxide layers on the raised diffusion guard ring and the raised diffusion structure.

9. The LOCOS-based junction-pinched Schottky rectifier according to claim 1, wherein the metal contact region is patterned through a masking photoresist layer being formed over the outer LOCOS field oxide layer, the plurality of inner LOCOS field oxide layers, and thermal oxide layers on the raised diffusion guard ring and the raised diffusion structure.

10. A LOCOS-based junction-pinched Schottky rectifier, comprising:
a semiconductor substrate of a first conductivity type, wherein the semiconductor substrate comprises a lightly-doped epitaxial silicon layer being formed on a heavily-doped silicon substrate;
a diffusion guard ring of a second conductivity type being surrounded by an outer LOCOS field oxide layer and formed in a surface portion of the lightly-doped epitaxial silicon layer, wherein a raised diffusion structure of the second conductivity type being surrounded by the raised diffusion guard ring is simultaneously formed in surface portions of the lightly-doped epitaxial silicon layer;
a plurality of recessed semiconductor surfaces being formed on the lightly-doped epitaxial silicon layer surrounded by the raised diffusion guard ring and the raised diffusion structure, wherein the plurality of recessed semiconductor surfaces are formed by removing a plurality of inner LOCOS field oxide layers being formed on a plurality of compensated diffusion layers in surface portions of the lightly-doped epitaxial silicon layer;
a metal contact region being formed on a portion of the raised diffusion guard ring, the plurality of compensated diffusion layers, and the raised diffusion structure; and
a Schottky metal layer being at least formed over the metal contact region.

11. The LOCOS-based junction-pinched Schottky rectifier according to claim 10, wherein the raised diffusion structure comprises a raised diffusion grid, a plurality of raised diffusion stripes, or a plurality of raised diffusion rings.

12. The LOCOS-based junction-pinched Schottky rectifier according to claim 10, wherein the plurality of compensated diffusion layers are formed by implanting doping impurities of the second conductivity type across pad oxide layers outside of patterned masking silicon nitride layers into surface portions of the lightly-doped epitaxial silicon layer before performing a local oxidation of silicon (LOCOS) process.

13. The LOCOS-based junction-pinched Schottky rectifier according to claim 10, wherein the raised diffusion guard ring and the raised diffusion structure are formed by implanting doping impurities of the second conductivity type across patterned pad oxide layers formed between the outer LOCOS field oxide layer and the plurality of inner LOCOS field oxide layers into surface portions of the lightly-doped epitaxial silicon layer after removing patterned masking silicon nitride layers.

14. The LOCOS-based junction-pinched Schottky rectifier according to claim 10, wherein the raised diffusion guard ring and the raised diffusion structure are formed by a thermal diffusion process using a liquid source, a solid source, or a gas source after removing patterned pad oxide layers formed between the outer LOCOS field oxide layer and the plurality of inner LOCOS field oxide layers.

15. The LOCOS-based junction-pinched Schottky rectifier according to claim 10, wherein the Schottky metal layer comprises a refractory metal silicide layer being formed by a self-aligned silicidation process.

16. A LOCOS-based junction-pinched Schottky rectifier, comprising:
a semiconductor substrate of a first conductivity type, wherein the semiconductor substrate comprises a lightly-doped epitaxial silicon layer being formed on a heavily-doped silicon substrate;
a raised diffusion guard ring of a second conductivity type being surrounded by an outer LOCOS field oxide layer and formed in a surface portion of the lightly-doped epitaxial silicon layer, wherein a raised diffusion structure of the second conductivity type being surrounded by the raised diffusion guard ring is simultaneously formed in surface portions of the lightly-doped epitaxial silicon layer;
a plurality of recessed semiconductor surfaces being formed on the lightly-doped epitaxial silicon layer between the raised diffusion guard ring and the raised diffusion structure, wherein the plurality of recessed semiconductor surfaces are formed by removing a plurality of inner LOCOS field oxide layers;
a Schottky metal contact region being formed on a portion of the raised diffusion guard ring, the plurality of recessed semiconductor surfaces, and the raised diffusion structure; and
a metal layer being at least formed over the Schottky metal contact region.

17. The LOCOS-based junction-pinched Schottky rectifier according to claim 16, wherein a plurality of compensated diffusion layers of the first conductivity type are formed in surface portions of the lightly-doped epitaxial silicon layer under the plurality of recessed semiconductor surfaces and the outer LOCOS field oxide layer.

18. The LOCOS-based junction-pinched Schottky rectifier according to claim 16, wherein the outer LOCOS field oxide layer and the plurality of inner LOCOS field oxide layers are formed by a local oxidation of silicon (LOCOS) process in a steam or wet oxygen ambient and at an oxidation temperature between 950 and 1100.

19. The LOCOS-based junction-pinched Schottky rectifier according to claim 16, wherein the raised diffusion structure comprises a raised diffusion grid, a plurality of raised diffusion rings, or a plurality of raised diffusion stripes.

20. The LOCOS-based junction-pinched Schottky rectifier according to claim 16, wherein the raised diffusion guard ring and the raised diffusion structure are simultaneously formed by ion implantation or a thermal diffusion process using a liquid source, a solid source, or a gas source.
